(19) United States
(12) Patent Application Publication
(10) Pub. No.: US 2026/0047231 A1
(43) Pub. Date: Feb. 12, 2026

(54) OPTICAL SENSOR PACKAGE AND METHOD OF MANUFACTURING THE SAME

(71) Applicant: KT&G CORPORATION, Daejeon (KR)

(72) Inventors: Sang Cheol PARK, Suwon-si (KR); Seung Uk PARK, Cheonan-si (KR); Jin Chul JUNG, Daejeon (KR); Won Kyeong LEE, Guri-si (KR)

(73) Assignee: KT&G CORPORATION, Daejeon (KR)

(21) Appl. No.: 19/262,207

(22) Filed: Jul. 8, 2025

(30) Foreign Application Priority Data
Aug. 7, 2024 (KR) 10-2024-0105645

(51) Int. Cl. H10F 77/50; H01L 21/56; H01L 23/31; H01L 25/075; H01L 25/16; H01L 25/18; H10D 80/30; H10F 39/00; H10F 39/10; H10F 39/90; H10H 29/01; H10H 29/20; H10H 29/853

(52) U.S. Cl. CPC H10F 77/50; H01L 21/565; H01L 23/3121; H01L 25/0753; H01L 25/165; H01L 25/167; H01L 25/18; H10D 80/30; H10F 39/011; H10F 39/107; H10F 39/90; H10H 29/0362; H10H 29/20; H10H 29/853

(57) ABSTRACT

An optical sensor package includes a light-emitting unit disposed on a package substrate and configured to emit first light toward a target, a light-receiving unit disposed on the package substrate and configured to receive second light obtained when the first light is reflected from the target, and a molding member formed on the package substrate to surround a top surface of an exposed portion of the package substrate, the light-emitting unit, and the light-receiving unit, the molding member including a groove formed in a thickness direction between the light-emitting unit and the light-receiving unit, wherein the groove is filled with an opaque material.

### CROSS-REFERENCE TO RELATED APPLICATION

This application is based on and claims priority under 35 U.S. C. § 119 to Korean Patent Application No. 10-2024-0105645, filed on Aug. 7, 2024, in the Korean Intellectual Property Office, the disclosure of which is incorporated by reference herein in its entirety.

### BACKGROUND

1. Field

The disclosure relates to an optical sensor package and a method of manufacturing the same.

### 2. Description of the Related Art

There are various types of semiconductor packages depending on the technical requirements of each field of application. Recently, semiconductor packages have been required to be lightweight and compact and have electrical characteristics such as low power consumption, stable and fast signal wiring design, and technologies that prevent the inflow of contaminants from the outside.

For example, in the field of electronic cigarettes in which aerosol generating articles having nicotine are electrically heated to produce an aerosol, an optical sensor may be required to identify whether an aerosol generating article (e.g., a cigarette) is inserted into an aerosol generating device. Because such an optical sensor should be mounted on a small electronic device and needs to prevent the inflow of various contaminants generated after smoking, the optical sensor may be manufactured in the form of an optical sensor package.

The optical sensor detects the proximity of a subject by detecting, by using a light-receiving unit, light emitted from a light-emitting unit and reflected back to the subject. Accordingly, when crosstalk occurs in which light generated from the light-emitting unit is directly detected by the light-receiving unit, sensing sensitivity may deteriorate.

### SUMMARY

Provided is an optical sensor package capable of preventing light emitted from a light-emitting unit from being directly incident on a light-receiving unit.

Provided is a method of manufacturing an optical sensor package with reduced process time and manufacturing cost by minimizing a manufacturing process in a package manufacturing stage.

However, objectives to be achieved by the embodiments are not limited thereto, and other unmentioned objectives will be apparent to one of ordinary skill in the art to which the embodiments pertain from the present specification and the attached drawings.

Additional aspects will be set forth in part in the description which follows and, in part, will be apparent from the description, or may be learned by practice of the presented embodiments.

According to an embodiment, an optical sensor package includes a light-emitting unit disposed on a package substrate and configured to emit first light toward a target, a light-receiving unit disposed on the package substrate and configured to receive second light obtained when the first light is reflected from the target, and a molding member formed on the package substrate to surround a top surface of an exposed portion of the package substrate, the light-emitting unit, and the light-receiving unit, the molding member including a groove formed in a thickness direction between the light-emitting unit and the light-receiving unit, wherein the groove is filled with an opaque material.

According to another embodiment, a method of manufacturing an optical sensor package includes mounting sensor elements including a light-emitting unit and a light-receiving unit on each of substrate units, forming, on each of the substrate units, a molding member including a groove formed in a thickness direction between the light-emitting unit and the light-receiving unit, and filling the groove with an opaque material.

### BRIEF DESCRIPTION OF THE DRAWINGS

The above and other aspects, features, and advantages of certain embodiments will be more apparent from the following description taken in conjunction with the accompanying drawings, in which:

FIG. 1A is a plan view illustrating an optical sensor package, according to an embodiment;

FIG. 1B is a cross-sectional view illustrating the optical sensor package taken along line I-I′ of FIG. 1A;

FIG. 1C is a view for describing a sensing operation of the optical sensor package, according to an embodiment;

FIG. 2A is a plan view illustrating an optical sensor package, according to an embodiment; FIG. 2B is a cross-sectional view illustrating the optical sensor package taken along line II-II′ of FIG. 2A;

FIG. 3A is a plan view illustrating an optical sensor package, according to an embodiment; FIG. 3B is a cross-sectional view illustrating the optical sensor package taken along line III-III′ of FIG. 3A;

FIG. 4A is a plan view illustrating an optical sensor package, according to an embodiment; FIG. 4B is a cross-sectional view illustrating the optical sensor package taken along line IV-IV′ of FIG. 4A;

FIG. 5A is a plan view illustrating an optical sensor package, according to an embodiment; FIG. 5B is a cross-sectional view illustrating the optical sensor package taken along line V-V′ of FIG. 5A;

FIG. 6A is a plan view illustrating an optical sensor package, according to an embodiment; FIG. 6B is a cross-sectional view illustrating the optical sensor package taken along line VI-VI′ of FIG. 6A;

FIG. 7A is a plan view illustrating an optical sensor package, according to an embodiment; FIG. 7B is a cross-sectional view illustrating the optical sensor package taken along line VII-VII′ of FIG. 7A;

FIG. 8A is a plan view illustrating an optical sensor package, according to an embodiment; FIG. 8B is a cross-sectional view illustrating the optical sensor package taken along line VIII-VIII′ of FIG. 8A;

FIG. 9A is an external perspective view illustrating a substrate strip for an optical sensor package, according to an embodiment; FIG. 9B is a cross-sectional view illustrating the substrate strip taken along line X-X′ of FIG. 9A;

FIGS. 10 to 15 are cross-sectional views sequentially illustrating a process of manufacturing the substrate strip for an optical sensor package of FIGS. 9A and 9B;

FIG. 16 is a flowchart for describing a method of manufacturing an optical sensor package, according to an embodiment;

FIG. 17 is a cross-sectional view illustrating a substrate strip for an optical sensor package, according to another embodiment; and

FIGS. 18 to 20 are cross-sectional views for describing a process of manufacturing the substrate strip for an optical sensor package of FIG. 17.

### DETAILED DESCRIPTION

With respect to the terms used to describe in the various embodiments, the general terms which are currently and widely used are selected in consideration of functions of structural elements in the various embodiments of the present disclosure. However, meanings of the terms can be changed according to intention, a judicial precedence, the appearance of a new technology, and the like. In addition, in certain cases, a term which is not commonly used can be selected. In such a case, the meaning of the term will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “or”, and “module” described in the specification mean units for processing at least one function and operation and can be implemented by hardware components or software components and combinations thereof.

Hereinafter, embodiments are described in detail with reference to the accompanying drawings so that one of ordinary skill in the art to which the disclosure pertains easily implements the embodiments. However, the disclosure may be embodied in many different forms and is not limited to the embodiments set forth herein.

Hereinafter, embodiments will be described in detail with reference to the drawings.

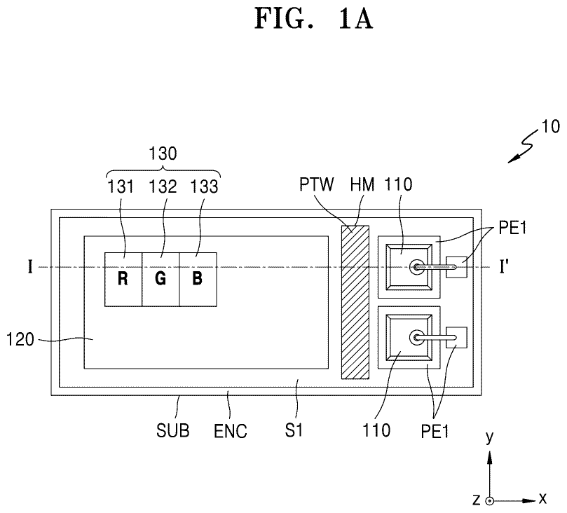

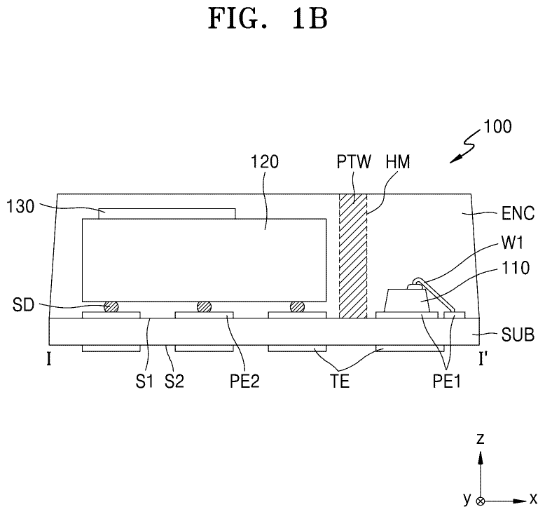

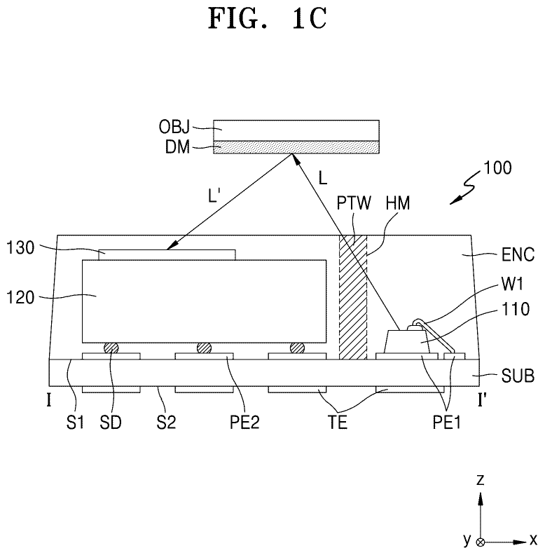

FIG. 1A is a plan view illustrating an optical sensor package, according to an embodiment. FIG. 1B is a cross-sectional view illustrating the optical sensor package taken along line I-I′ of FIG. 1A. FIG. 1C is a view for describing a sensing operation of the optical sensor package, according to an embodiment.

Referring to FIGS. 1A to 1C, an optical sensor package 100 according to an embodiment may include a package substrate SUB, a light-emitting unit 110, a semiconductor chip 120, a light-receiving unit 130, a molding member ENC, and a partition wall PTW.

In an embodiment, in the package substrate SUB, a first element PE1 and a second element PE2 may be formed on a first surface S1 (e.g., a surface in a +Z direction), and a substrate terminal TE may be formed on a second surface S2 (e.g., a surface in a-z direction) opposite to the first surface S1.

In an embodiment, the first surface S1 may be a surface facing a detection target OBJ of the optical sensor package 100. The substrate terminal TE may be electrically and/or physically connected to an electronic device (e.g., an aerosol generating device, a mobile phone, or a laptop) on which the optical sensor package 100 of the disclosure is mounted.

In an embodiment, the light-emitting unit 110 may be disposed on the package substrate SUB, and may emit first light toward the detection target OBJ. The light-emitting unit 110 may include at least one light-emitting diode that emits the first light when current flows. For example, the light-emitting unit 110 of FIGS. 1A to 1C may be any one of a visible light-emitting diode, an infrared light-emitting diode, and an ultraviolet light-emitting diode.

In an embodiment, the light-receiving unit 130 may be directly disposed on the package substrate SUB. Although the light-receiving unit 120 is disposed on the semiconductor chip 120 in FIGS. 1A to 1C, according to design requirements, the semiconductor chip 120 may be mounted on a separate printed circuit board, rather than the optical sensor package 100, and may be electrically connected to the light-receiving unit 130.

Also, the light-receiving unit 130 may receive second light obtained when the first light is reflected from the detection target OBJ. Although an embodiment in which an identification material DM is provided on one surface of the detection target OBJ is illustrated in FIGS. 1A to 1C, according to design requirements, the identification material DM may not be provided on one surface of the detection target OBJ. In this case, a wavelength band of the second light may be substantially the same as a wavelength band of the first light.

In an embodiment, the molding member ENC may be disposed on the first surface S1 of the package substrate SUB. The molding member ENC may protect the first surface S1 of the package substrate SUB and other components (e.g., the light-emitting unit 110, the semiconductor chip 120, and the light-receiving unit 130) mounted on the first surface S1. The molding member ENC may be formed of a non-conductive material. The molding member ENC may reduce or prevent the first surface S1 of the package substrate SUB and other components mounted on the first surface S1 from being electrically disconnected or unnecessarily shorted.

In an embodiment, the molding member ENC may be formed on the first surface S1 of the package substrate SUB to surround the light-emitting unit 110, the semiconductor chip 120, and the light-receiving unit 130.

In an embodiment, the molding member ENC may be formed of a light-transmitting material. For example, the molding member ENC may include a clear molding compound (CMC). The molding member ENC may guide light emitted from the light-emitting unit 110 to be transmitted to the detection target of the optical sensor package 100.

In an embodiment, the molding member ENC may be formed as a single body by connecting areas surrounding the light-emitting unit 110, the semiconductor chip 120, and the light-receiving unit 130. The molding member ENC may be substantially uniformly applied and cured onto the first surface S1 of the package substrate SUB. The molding member ENC formed as a single body may improve the efficiency of manufacturing the optical sensor package 100.

In an embodiment, the molding member ENC may include the partition wall PTW between the light-emitting unit 110 and the light-receiving unit 130 (or the semiconductor chip 120). The partition wall PTW may be located between the light-emitting unit 110 and the light-receiving unit 130 to prevent light emitted from the light-emitting unit 110 from being directly incident on the light-receiving unit 130.

According to a method of manufacturing the optical sensor package 100 described below, the partition wall PTW may be formed through a dispensing molding technique.

In detail, the molding member ENC formed through a transfer molding technique may include a groove HM formed in a thickness direction between the light-emitting unit 110 and the light-receiving unit 130 (or the semiconductor chip 120). For example, the groove HM may have a rectangular parallelepiped shape.

The groove HM of the molding member ENC may be filled with an opaque material. The opaque material may be preferably formed of a material having a low light transmittance to light emitted from the light-emitting unit in order to reduce the incidence of light emitted from the light-emitting unit 110 on the light-receiving unit 130. For example, the opaque material may be a black epoxy molding compound (EMC). In this case, the opaque material may be considered as a low-reflectivity material in that the opaque material absorbs mot of light output from the light-emitting unit 110.

Because the partial wall PTW is a result of curing a liquid opaque material in the groove HM, the partition wall PTW and the opaque material may be interchangeably used.

In an embodiment, a bottom surface of the partition wall PTW (or the opaque material) may contact the package substrate SUB, and a top surface of the partition wall PTW (or the opaque material) may be exposed to the outside.

In an embodiment, the top surface of the partition wall PTW (or the opaque material) may be coplanar with a top surface of the molding member ENC, and side surfaces connecting the top surface and the bottom surface of the partition wall PTW (or the opaque material) may contact the molding member ENC. In other words, the groove HM may have a well structure with boundary surfaces where the partition wall PTW (or the opaque material) and the molding member ENC contact each other as side surfaces and the package substrate SUB as a bottom surface.

As such, because the optical sensor package 100 includes the partition wall PTW between the light-emitting unit 110 and the light-receiving unit 130, crosstalk in which light emitted from the light-emitting unit 110 is directly incident on the light-receiving unit 130 may be prevented, thereby improving the sensing sensitivity of the optical sensor package 100.

According to another embodiment, the identification material DM may be provided on one surface of the detection target OBJ. The identification material DM may be excited by absorbing light of a certain wavelength range, and in this case, when a ‘material is excited’, it may mean that a state of the material changes from a ground state to an excited state. Next, in a process of changing the state of the identification material DM from the excited state to the ground state, light of a certain wavelength range may be emitted from a light-emitting material.

In an embodiment, the identification material DM may be excited by light emitted from the light-emitting unit 110 and may emit light of a wavelength range different from a wavelength range of the emitted light. For example, the identification material DM may be excited by light of a first wavelength range emitted from the light-emitting unit 110 and may emit light of a second wavelength range different from the first wavelength range. In this case, the first light emitted from the light-emitting unit 110 may be light of the first wavelength, and the second light received by the light-receiving unit 130 may be light of the second wavelength. That is, a wavelength band of the second light may be different from a wavelength band of the first light.

The identification material DM may be a material included in lanthanide series, and may include a material including at least one element among elements with atomic numbers 57 to 71.

For example, the identification material DM may be a first light-emitting material that is excited by light of a first wavelength range of about 350 nm to about 390 nm and emits light of a second wavelength range of about 400 nm to about 750 nm. Accordingly, the light-emitting unit 110 may emit ultraviolet light of about 365 nm for the first light-emitting material, and the light-receiving unit 130 may sense visible light (i.e., red light) of 700 nm emitted from the first light-emitting material.

In an embodiment, the light-emitting unit 110 may include at least one light-emitting diode that emits light L of a first wavelength when current flows. For example, both two light-emitting units 110 shown in FIGS. 1A to 1C may include ultraviolet light-emitting diodes.

In an embodiment, the semiconductor chip 120 may include an application specific integrated circuit (ASIC) that controls an overall operation of the optical sensor package 100.

In an embodiment, the light-receiving unit 130 may include at least one light-receiving diode through which current flows when receiving light L′ of a second wavelength different from the light L of the first wavelength. For example, the light-receiving unit 130 of FIGS. 1A to 1C may be an RGB detection sensor. The RGB detection sensor may include a first photodiode 131 for detecting red light, a second photodiode 132 for detecting green light, and a third photodiode 133 for detecting blue light. The RGB detection sensor may detect a color of the light L′ of the second wavelength based on a ratio of the amount of light received from each of the first photodiode 131, the second photodiode 132, and the third photodiode 133.

In an embodiment, the optical sensor package 100 may include a first element PE1, a second element PE2, and a first conductive member W1.

In an embodiment, the first element PE1 and the second element PE2 may be formed on the first surface S1. The first element PE1 may be connected to the light-emitting unit 110 including a light-emitting diode, and the second element PE2 may be connected to the semiconductor chip 120.

In an embodiment, the first conductive member W1 may electrically connect the first element PE1 to the light-emitting unit 110. For example, the first element PE1 may include two terminals including a negative electrode terminal and a positive electrode terminal. The light-emitting unit 110 may be directly coupled to any one of the two terminals. The first conductive member W1 may connect the light-emitting unit 110 to the other of the two terminals.

Also, a solder ball SD may electrically connect the second element PE2 to the semiconductor chip 120. For example, the second element PE2 may include a plurality of terminals corresponding to pad electrodes formed on a rear surface of the semiconductor chip 120. The semiconductor chip 120 may be connected to the second element PE2 through a reflow process by arranging the solder ball SD between the pad electrodes of the semiconductor chip 120 and the plurality of electrodes of the second element PE2.

In an embodiment, the first element PE1 and the second element PE2 may be disposed adjacent to each other on the first surface S1. Accordingly, the light-emitting unit 110 and the semiconductor chip 120 may be disposed adjacent to each other on the first surface S1 of the package substrate SUB.

In an embodiment, the light-receiving unit 130 may be disposed on the semiconductor chip 120. For example, the light-receiving unit 130 may be integrally manufactured when the semiconductor chip 120 is produced. Although the light-receiving unit 130 is disposed on an upper left portion of the semiconductor chip 120 and the area of the light-receiving unit 130 is about ¼ of the semiconductor chip 120 in FIG. 1A, this is only an example and the disclosure is not limited thereto. That is, the size and the arrangement of the light-receiving unit 130 may be modified in various ways according to the request of a customer.

According to an embodiment, a height H1 from the first surface S1 (or a top surface) of the package substrate SUB to a top surface of the semiconductor chip 120 may be greater than a height H2 from the first surface S1 (or the top surface) of the package substrate SUB to a top surface of the light-emitting unit 110. For example, the height H1 from the first surface S1 (or the top surface) of the package substrate SUB to the top surface of the semiconductor chip 120 may be about 610 μm, and the height H2 from the first surface S1 (or the top surface) of the package substrate SUB to the top surface of the light-emitting unit 110 may be about 150 μm.

As such, when the height H1 from the first surface S1 (or the top surface) of the package substrate SUB to the top surface of the semiconductor chip 120 is greater than the height H2 from the first surface S1 (or the top surface) of the package substrate SUB to the top surface of the light-emitting unit 110, because the light-receiving unit 130 is disposed on the semiconductor chip 120, the light L emitted from the light-emitting unit 110 may be prevented from being directly incident on the light-receiving unit 130 without passing through the detection target OBJ. That is, because light emitted from the light-emitting unit 110 is shielded, the semiconductor chip 120 may further complement a partition wall function.

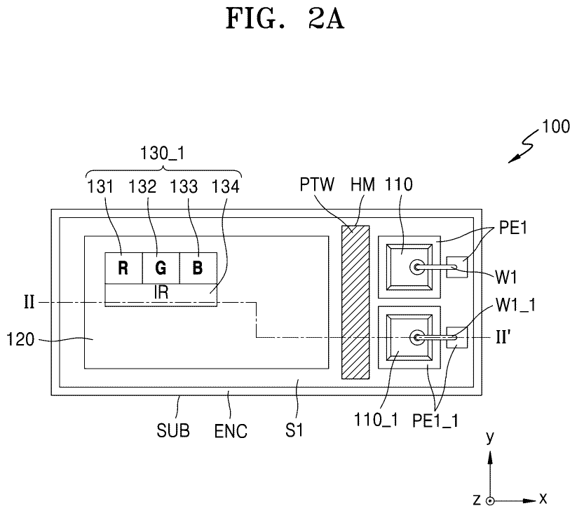

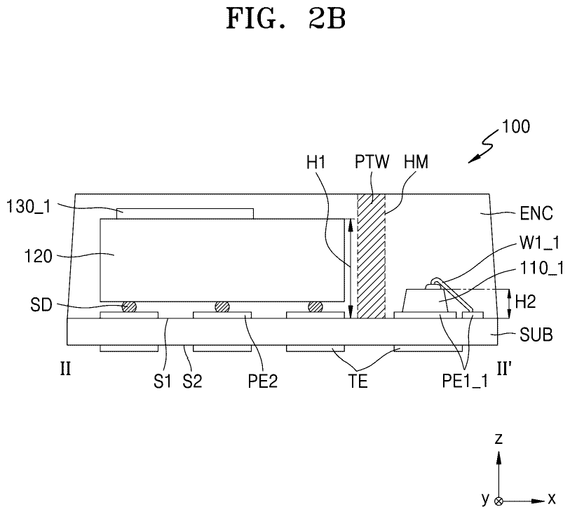

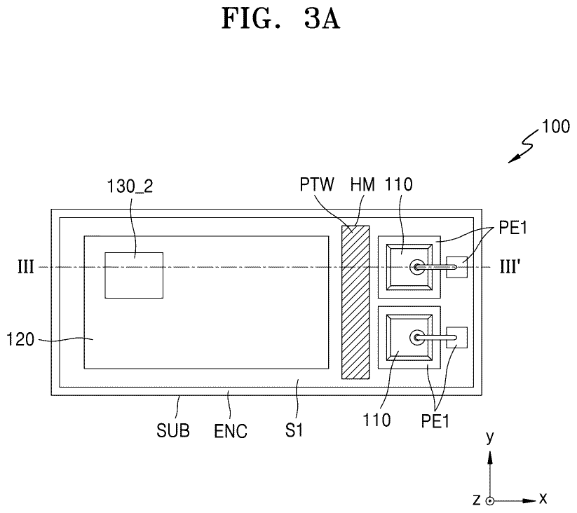

FIG. 2A is a plan view illustrating an optical sensor package, according to an embodiment. FIG. 2B is a cross-sectional view illustrating the optical sensor package taken along line II-II′ of FIG. 2A.

The optical sensor package 100 of FIGS. 2A and 2B is substantially the same as the optical sensor package 100 of FIGS. 1A to 1C, except that the optical sensor package 100 of FIGS. 2A and 2B further includes an infrared light-emitting diode and an infrared light-receiving diode whereas the optical sensor package 100 of FIGS. 1A to 1C includes only an ultraviolet light-emitting diode and an RGB detection sensor. Hereinafter, a difference will be mainly described, and the same description as that made above will be omitted.

Referring to FIGS. 2A and 2B, the optical sensor package 100 according to an embodiment may include the package substrate SUB, light-emitting units 110 and 110_1, the semiconductor chip 120, a light-receiving unit 130_1, the molding member ENC, and the partition wall PTW.

The identification material DM may be provided on one surface of the detection target OBJ (see FIG. 1C).

The identification material DM may be excited by absorbing light of a certain wavelength range, and in this case, when a ‘material is excited’, it may mean that a state of the material changes from a ground state to an excited state. Next, in a process of changing the state of the identification material DM from the excited state to the ground state, light of a certain wavelength range may be emitted from a light-emitting material.

In an embodiment, the identification material DM may be excited by light emitted from the light-emitting unit 110 and may emit light of a wavelength range different from a wavelength range of the emitted light. For example, the identification material DM may be excited by light of a first wavelength range emitted from the light-emitting unit 110 and may emit light of a second wavelength range different from the first wavelength range.

For example, the identification material DM may be a first light-emitting material that is excited by light of a first wavelength range of about 350 nm to about 390 nm and emits light of a second wavelength range of about 400 nm to about 750 nm. Accordingly, the light-emitting unit 110 may emit ultraviolet light of about 365 nm for the first light-emitting material, and the light-receiving unit 130 may sense visible light (i.e., red light) of 700 nm emitted from the first light-emitting material.

In another example, the identification material DM may be a second light-emitting material that is excited by light of a first wavelength range of about 300 nm to about 340 nm and emits light of a second wavelength range of about 1000 nm to about 1020 nm. Accordingly, the light-emitting unit 110 may emit ultraviolet light of about 325 nm for the second light-emitting material, and the light-receiving unit 130_1 may sense infrared light of 1012 nm emitted from the second light-emitting material.

In another embodiment, the identification material DM may be a third light-emitting material that is excited by light of a first wavelength range of about 930 nm to about 990 n and emits light of a second wavelength range of about 1000 nm to about 1020 nm. Accordingly, the light-emitting unit 110 may emit infrared light of about 980 nm for the third light-emitting material, and the light-receiving unit 130 may sense infrared light of about 1012 nm emitted from the third light-emitting material.

The embodiment of FIGS. 2A and 2B may include the light-emitting unit 110 including an ultraviolet light-emitting diode and the light-emitting unit 110_1 including an infrared light-emitting diode.

In an embodiment, the semiconductor chip 120 may include an application specific integrated circuit (ASIC) that controls an overall operation of the optical sensor package 100.

In an embodiment, the light-receiving unit 130_1 may include at least one light-receiving diode through which current flows when receiving the light L′ of the second wavelength different from the light L of the first wavelength. For example, the light-receiving unit 130_1 of FIGS. 2A and 2B may be an RGB detection sensor. The RGB detection sensor may include the first photodiode 131 for detecting red light, the second photodiode 132 for detecting green light, and the third photodiode 133 for detecting blue light therein. Also, the light-receiving unit 130_1 may further include an infrared light-receiving diode 134 for receiving light of an infrared wavelength (i.e., about 1000 nm to about 1020 nm).

Accordingly, when light emitted from the light-emitting unit 110 including the ultraviolet light-emitting diode may be detected by the RGB detection sensors 131, 132, and 133 of the light-receiving unit 130_1 when the detection material included in the detection target is the first light-emitting material and may be detected by the infrared light-receiving diode 134 of the light-receiving unit 130_1 when the identification material is the second light-emitting material.

Also, when the identification material included in the detection target is the third light-emitting material, the infrared light of the first wavelength emitted from the light-emitting unit 110_1 including the infrared light-emitting diode may be excited by the infrared light of the second wavelength and may be detected by the infrared light-receiving diode 134 of the light-receiving unit 130_1. On the other hand, the infrared light of the first wavelength emitted from the light-emitting unit 110_1 including the infrared light-emitting diode may be detected as it is by the infrared light-receiving diode 134 of the light-receiving unit 130_1.

In an embodiment, the optical sensor package 100 may include a first conductive member W1_1. In an embodiment, the first conductive member W1_1 may electrically connect a first element PE1_1 to the light-emitting unit 110_1.

In an embodiment, the light-receiving unit 130_1 may be disposed on the semiconductor chip 120. Also, the height H1 from the first surface S1 (or a top surface) of the package substrate SUB to a top surface of the semiconductor chip 120 may be greater than the height H2 from the first surface S1 (or the top surface) of the package substrate SUB to a top surface of the light-emitting unit 110.

As described with reference to FIGS. 1A to 1C, the optical sensor package 100 of FIGS. 2A and 2B includes the partition wall PTW and the semiconductor chip 120 further complements a partition wall function, thereby preventing crosstalk and improving the sensing sensitivity of the optical sensor package 100.

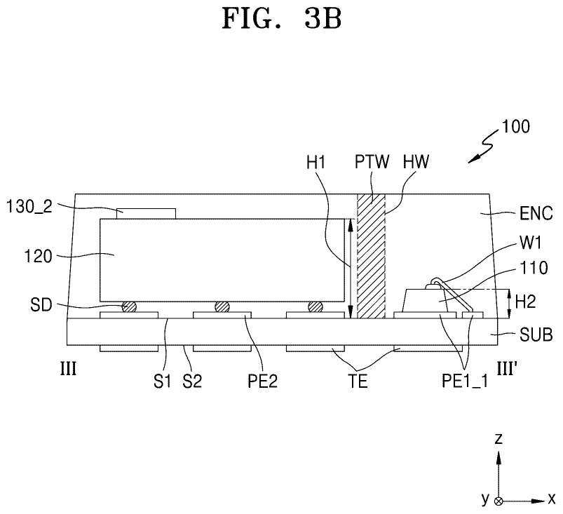

FIG. 3A is a plan view illustrating an optical sensor package, according to an embodiment. FIG. 3B is a cross-sectional view illustrating the optical sensor package taken along line III-III′ of FIG. 3A.

The optical sensor package 100 of FIGS. 3A and 3B is substantially the same as the optical sensor package 100 of FIGS. 1A to 1C, except that the optical sensor package 100 of FIGS. 3A and 3B includes an infrared photodiode, instead of an RGB detection sensor included in the optical sensor package 100 of FIGS. 1A to 1C. Hereinafter, a difference will be mainly described, and the same description as that made above will be omitted.

Referring to FIGS. 3A and 3B, the optical sensor package 100 according to an embodiment may include the package substrate SUB, the light-emitting unit 110, the semiconductor chip 120, a light-receiving unit 130_2, the molding member ENC, and the partition wall PTW.

The identification material DM may be provided on one surface of the detection target OBJ (see FIG. 1C).

The identification material DM may be excited by absorbing light of a certain wavelength range, and in this case, when a ‘material is excited’, it may mean that a state of the material changes from a ground state to an excited state. Next, in a process of changing the state of the identification material DM from the excited state to the ground state, light of a certain wavelength range may be emitted from a light-emitting material.

In an embodiment, the identification material DM may be excited by light emitted from the light-emitting unit 110 and may emit light of a wavelength range different from a wavelength range of the emitted light. For example, the identification material DM may be excited by light of a first wavelength range emitted from the light-emitting unit 110 and may emit light of a second wavelength range different from the first wavelength range.

For example, the identification material DM may be a second light-emitting material that is excited by light of a first wavelength range of about 300 nm to about 340 nm and emits light of a second wavelength range of about 1000 nm to about 1020 nm. Accordingly, the light-emitting unit 110 may emit ultraviolet light of about 325 nm for the second light-emitting material, and the light-receiving unit 130_2 may sense infrared light of 1012 nm emitted from the second light-emitting material.

Two light-emitting units 110 shown in FIGS. 3A and 3B may be ultraviolet light-emitting diodes.

In an embodiment, the semiconductor chip 120 may include an application specific integrated circuit (ASIC) that controls an overall operation of the optical sensor package 100.

In an embodiment, the light-receiving unit 130_2 may include at least one light-receiving diode through which current flows when receiving the light L′ of the second wavelength different from the light L of the first wavelength. For example, the light-receiving unit 130_2 of FIGS. 2A and 2B may include an infrared light-receiving diode capable of receiving light of an infrared wavelength (i.e., about 1000 nm to about 1020 nm).

Accordingly, light emitted from the light-emitting unit 110 including the ultraviolet light-emitting diode may be detected by the infrared light-receiving diode of the light-receiving unit 130_2 when the identification material included in the detection target is the second light-emitting material.

In an embodiment, the light-receiving unit 130_2 may be disposed on the semiconductor chip 120. Also, the height H1 from the first surface S1 (or a top surface) of the package substrate SUB to a top surface of the semiconductor chip 120 may be greater than the height H2 from the first surface S1 (or the top surface) of the package substrate SUB to a top surface of the light-emitting unit 110.

As described with reference to FIGS. 1A to 1C, because the optical sensor package 100 of FIGS. 3A and 3B includes the partition wall PTW and the semiconductor chip 120 further complements a partition wall function, crosstalk may be prevented, thereby improving the sensing sensitivity of the optical sensor package 100.

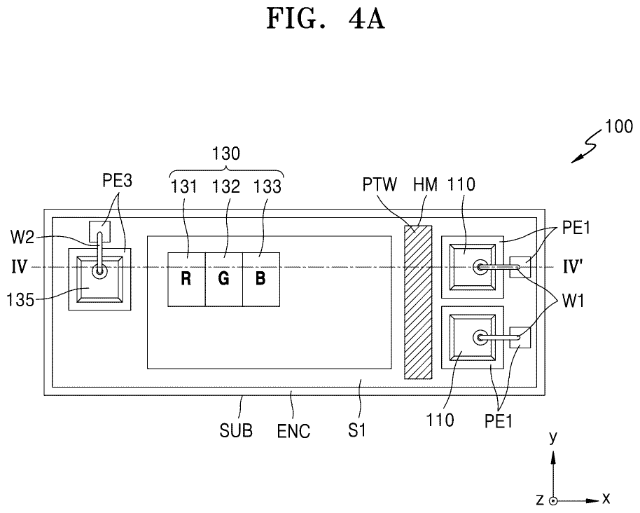

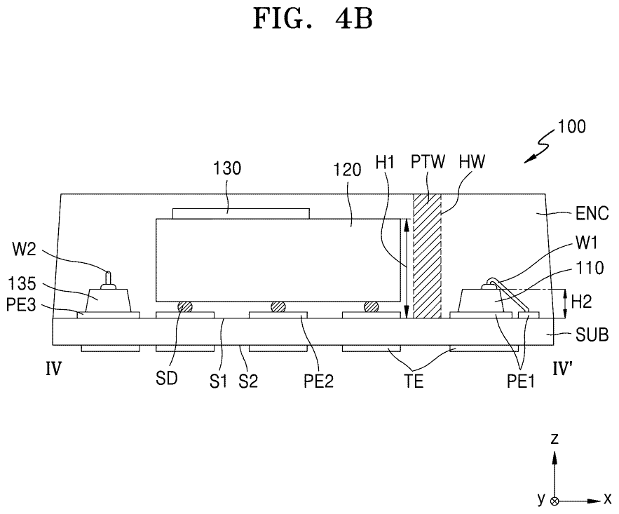

FIG. 4A is a plan view illustrating an optical sensor package, according to an embodiment. FIG. 4B is a cross-sectional view illustrating the optical sensor package taken along line IV-IV′ of FIG. 4A.

The optical sensor package 100 of FIGS. 4A and 4B is substantially the same as the optical sensor package 100 of FIGS. 1A to 1C, except that the optical sensor package 100 of FIGS. 4A and 4B further includes an additional light-receiving unit 135. Hereinafter, a difference will be mainly described, and the same description as that made above will be omitted.

Referring to FIGS. 4A and 4b, in an embodiment, the optical sensor package 100 may further include the additional light-receiving unit 135, a third element PE3, and a second conductive member W2.

In an embodiment, the third element PE2 may be formed on the first surface S1 of the package substrate SUB. The third element PE3 may be connected to the additional light-receiving unit 135 including an infrared light-receiving diode.

For example, the third element PE3 may include two terminals including a negative electrode terminal and a positive electrode terminal. The additional light-receiving unit 135 may be directly coupled to any one of the two terminals. The second conductive member W2 may connect the additional light-receiving unit 135 to the other of the two terminals.

In an embodiment, the third element PE3 may be disposed on the first surface S1 to be opposite to the first element PE1 with the second element PE2 therebetween, and may be disposed on the first surface S1 to be adjacent to the second element PE2. Also, the additional light-receiving unit 135 may be disposed on the first surface S1 to be opposite to the light-emitting unit 110 with the semiconductor chip 120 therebetween, and may be disposed on the first surface S1 to be adjacent to the semiconductor chip 120.

Because the semiconductor chip 120 is disposed between the additional light-receiving unit 135 and the light-emitting unit 110, the semiconductor chip 120 may have a partition wall function.

The identification material DM may be provided on one surface of the detection target OBJ (see FIG. 1C).

In an embodiment, the identification material DM may be excited by light emitted from the light-emitting unit 110 and may emit light of a wavelength range different from a wavelength range of the emitted light. For example, the identification material DM may be excited by light of a first wavelength range emitted from the light-emitting unit 110 and may emit light of a second wavelength range different from the first wavelength range.

For example, the identification material DM may be a first light-emitting material that is excited by light of a first wavelength range of about 350 nm to about 390 nm and emits light of a second wavelength range of about 400 nm to about 750 nm. Accordingly, the light-emitting unit 110 may emit ultraviolet light of about 365 nm for the first light-emitting material, and the light-receiving unit 130 may sense visible light (i.e., red light) of 700 nm emitted from the first light-emitting material.

In another example, the identification material DM may be a second light-emitting material that is excited by light of a first wavelength range of about 300 nm to about 340 nm and emits light of a second wavelength range of about 1000 nm to about 1020 nm. Accordingly, the light-emitting unit 110 may emit ultraviolet light of about 325 nm for the second light-emitting material, and the light-receiving unit 130_1 may sense infrared light of 1012 nm emitted from the second light-emitting material.

Accordingly, light emitted from the light-emitting unit 110 including the ultraviolet light-emitting diode may be detected by the RGB detection sensors 131, 132, and 133 of the light-receiving unit 130 when the identification material included in the detection target is the first light-emitting material and may be detected by the infrared light-receiving diode of the additional light-receiving unit 135 when the identification material is the second light-emitting material.

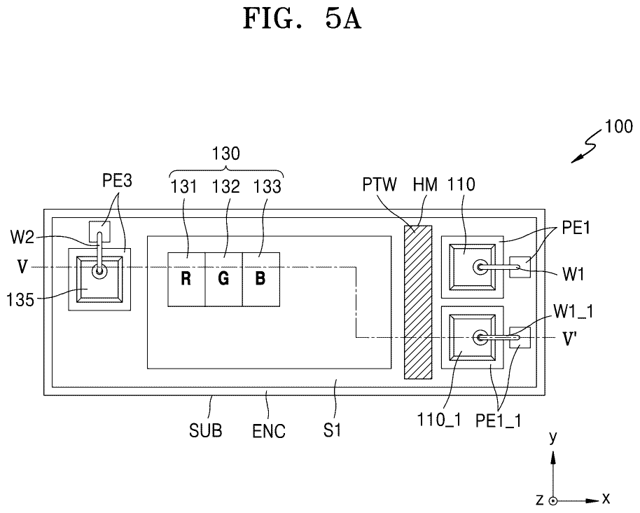

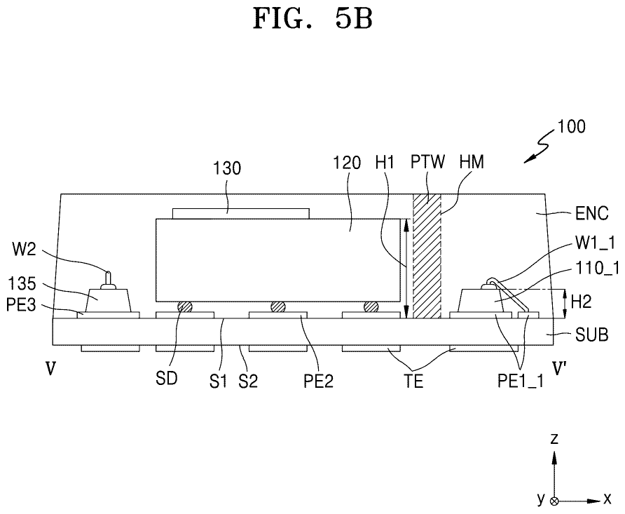

FIG. 5A is a plan view illustrating an optical sensor package, according to an embodiment. FIG. 5B is a cross-sectional view illustrating the optical sensor package taken along line V-V′ of FIG. 5A.

The optical sensor package 100 of FIGS. 5A and 5B is substantially the same as the optical sensor package 100 of FIGS. 4A and 4B, except that the optical sensor package 100 of FIGS. 5A and 5B includes the light-emitting unit 110 including an ultraviolet light-emitting diode and the light-emitting unit 110_1 including an infrared light-emitting diode whereas the optical sensor package 100 of FIGS. 4A and 4B includes only the light-emitting unit 110 including an ultraviolet light-emitting diode. Hereinafter, a difference will be mainly described, and the same description as that made above will be omitted.

In the optical sensor package 100, light emitted from the light-emitting unit 110 including the ultraviolet light-emitting diode may be detected by the RGB detection sensors 131, 132, and 133 of the light-receiving unit 130 when the identification material included in the detection target is a first light-emitting material and may be detected by the infrared light-receiving diode of the additional light-receiving unit 135 when the identification material is a second light-emitting material.

Also, when the identification material included in the detection target is a third light-emitting material, infrared light of a first wavelength emitted from the light-emitting unit 110_1 including the infrared light-emitting diode may be excited by infrared light of a second wavelength and may be detected by the infrared light-receiving diode of the additional light-receiving unit 135. The infrared light of the first wavelength emitted from the light-emitting unit 110_1 including the infrared light-emitting diode may be detected as it is by the infrared light-receiving diode of the additional light-receiving unit 135.

Because the semiconductor chip 120 is disposed between the additional light-receiving unit 135 and the light-emitting units 110 and 110_1, the semiconductor chip 120 may further complement a partition wall function.

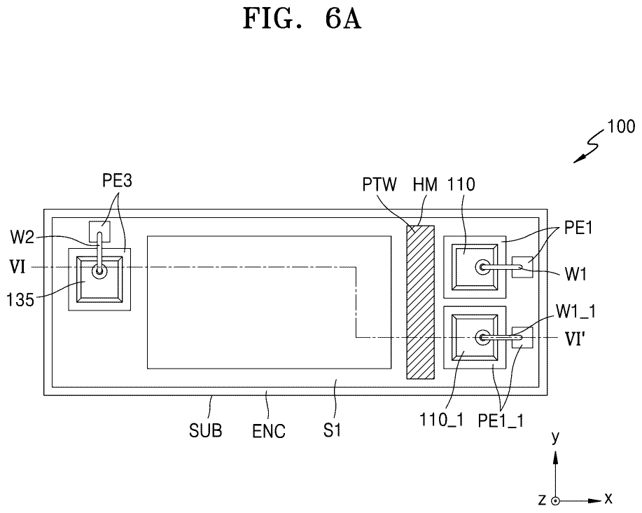

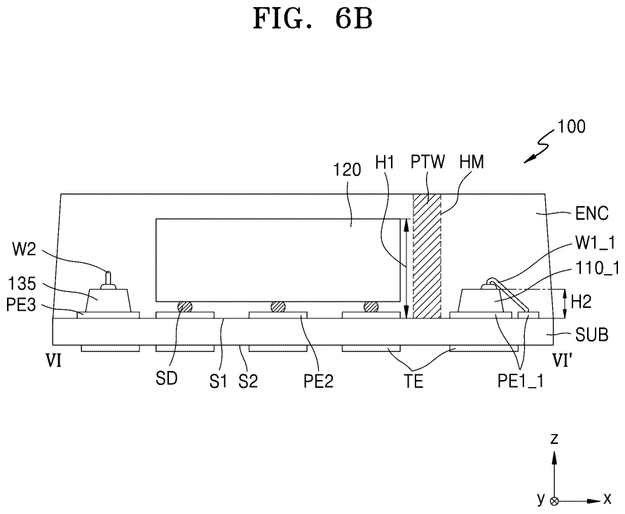

FIG. 6A is a plan view illustrating an optical sensor package, according to an embodiment. FIG. 6B is a cross-sectional view illustrating the optical sensor package taken along line VI-VI′ of FIG. 6A.

The optical sensor package 100 of FIGS. 6A and 6B is substantially the same as the optical sensor package 100 of FIGS. 5A and 5B, except that the optical sensor package 100 of FIGS. 6A and 6B does not include an RGB detection sensor and includes only the additional light-receiving unit 135 including an infrared light-receiving diode whereas the optical sensor package 100 of FIGS. 5A and 5B includes both an RGB detection sensor and the additional light-receiving unit 135 including an infrared light-receiving diode. Hereinafter, a difference will be mainly described, and the same description as that made above will be omitted.

In the optical sensor package 100 of FIGS. 6A and 6B, light emitted from the light-emitting unit 110 including an ultraviolet light-emitting diode may be detected by the infrared light-receiving diode of the additional light-receiving unit 135 when the identification material included in the detection target is a second light-emitting material.

Also, when the identification material included in the detection target is a third light-emitting material, infrared light of a first wavelength emitted from the light-emitting unit 110_1 including an infrared light-emitting diode may be excited by infrared light of a second wavelength and detected by the infrared light-receiving diode of the additional light-receiving unit 135. The infrared light of the first wavelength emitted from the light-emitting unit 110_1 including the infrared light-emitting diode may be detected as it is by the infrared light-receiving diode of the additional light-receiving unit 135.

Because the semiconductor chip 120 is disposed between the additional light-receiving unit 135 and the light-emitting units 110 and 110_1, the semiconductor chip 120 may further complement a partition wall function.

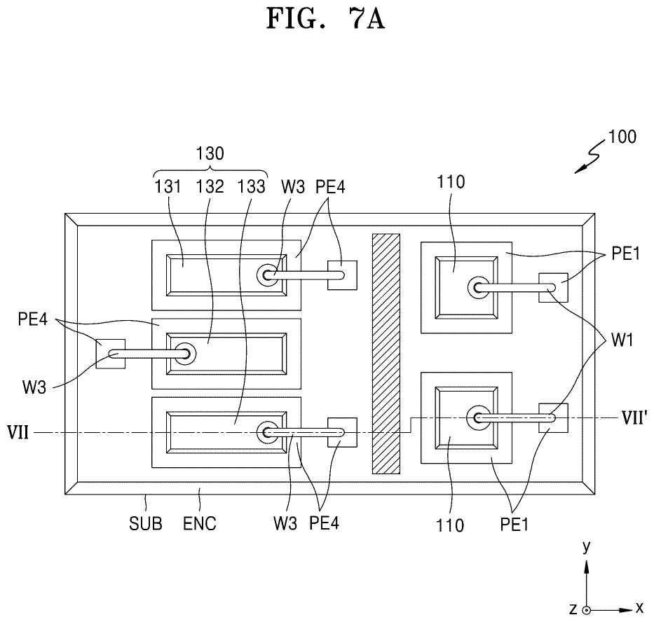

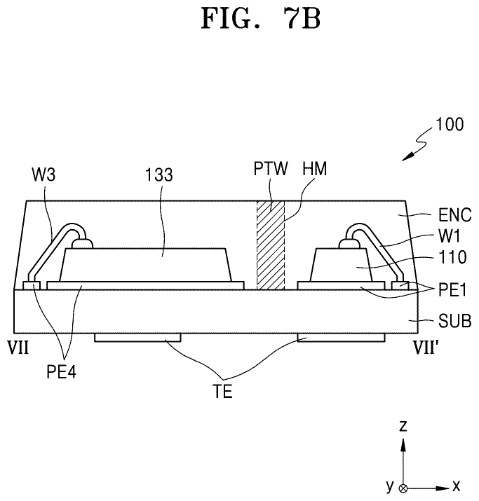

FIG. 7A is a plan view illustrating an optical sensor package, according to an embodiment. FIG. 7B is a cross-sectional view illustrating the optical sensor package taken along line VII-VII′ of FIG. 7A.

The optical sensor package 100 of FIGS. 7A and 7B is substantially the same as the optical sensor package 100 of FIGS. 1A to 1C, except that the optical sensor package 100 of FIGS. 7A and 7B does not include the semiconductor chip 120 and includes the light-receiving unit 130 including an RGB detection sensor whereas the optical sensor package 100 of FIGS. 1A to 1C includes the light-receiving unit 130 including an RGB detection sensor disposed on the semiconductor chip 120. Hereinafter, a difference will be mainly described, and the same description as that made above will be omitted.

Referring to FIGS. 7A and 7B, in an embodiment, the optical sensor package 100 may include the light-receiving unit 130 including the RGB detection sensor, a fourth element PE4, and a third conductive member W3.

In an embodiment, the fourth element PE4 may be formed on the first surface S1 of the package substrate SUB. The fourth element PE4 may be connected to the light-receiving unit 130 including the RGB detection sensor. The RGB detection sensor may include the first photodiode 131 for detecting red light, the second photodiode 132 for detecting green light, and the third photodiode 133 for detecting blue light.

For example, the fourth element PE4 may include two terminals including a negative electrode terminal and a positive electrode terminal. The first photodiode 131 may be directly coupled to any one of the two terminals. The third conductive member W3 may connect the first photodiode 131 to the other of the two terminals. The second photodiode 132 may be directly coupled to any one of the two terminals. The third conductive member W3 may connect the second photodiode 132 to the other of the two terminals. Likewise, the third photodiode 133 may be directly coupled to any one of the two terminals. The third conductive member W3 may connect the third photodiode 133 to the other of the two terminals.

As described with reference to FIGS. 1A to 1C, because the optical sensor package 100 of FIGS. 7A and 7B includes the partition wall PTW, crosstalk may be prevented, thereby improving the sensing sensitivity of the optical sensor package 100. Also, because the third photodiode 133 of FIGS. 7A and 7B is capable of sensing only visible light, the probability of crosstalk due to light emitted from the light-emitting unit 110 including an ultraviolet light-emitting element may not be high.

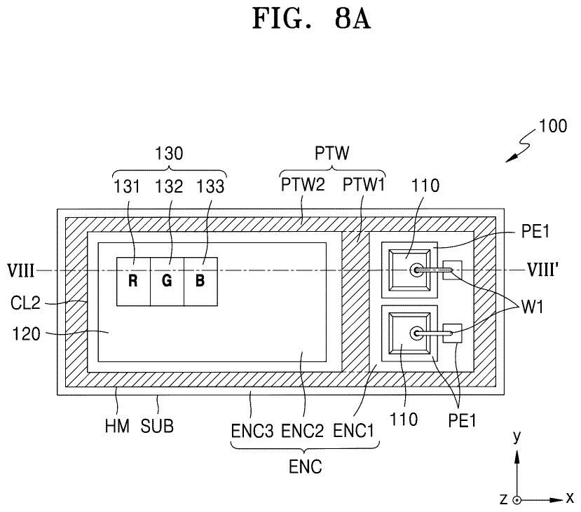

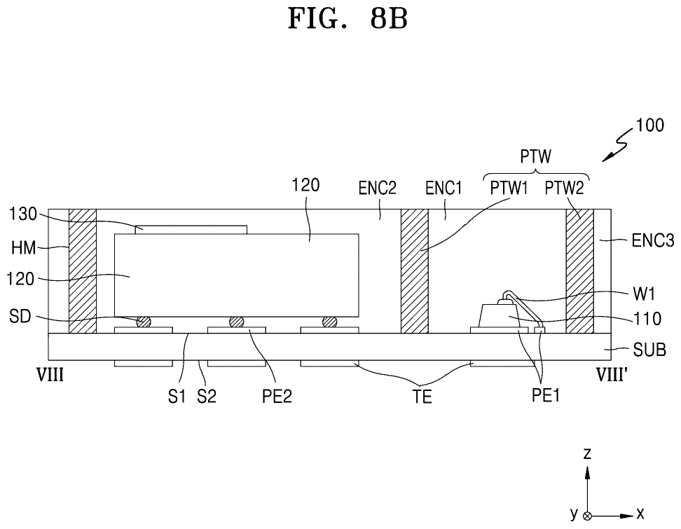

Although the partition wall PTW is located only between the light-receiving unit 130 and the light-emitting unit 110 in FIGS. 1A to 7B, the partition wall PTW in the optical sensor package 100 according to another embodiment may be additionally formed along a circumference of the package substrate SUB in addition to between the light-receiving unit 130 and the light-emitting unit 110 as shown in FIGS. 8A and 8B.

The optical sensor package 100 may include the molding member ENC disposed on a top surface of an exposed portion of the package substrate SUB, the light-emitting unit 110, the semiconductor chip 120, and the light-receiving unit 130.

In an embodiment, the molding member ENC may be formed of a light-transmitting material. For example, the molding member ENC may include a clear molding compound (CMC). The molding member ENC may guide light emitted from the light-emitting unit 110 to be transmitted to the detection target of the optical sensor package 100.

FIG. 8A is a plan view illustrating an optical sensor package, according to an embodiment. FIG. 8B is a cross-sectional view illustrating the optical sensor package taken along line VIII-VIII′ of FIG. 8A.

The optical sensor package 100 of FIGS. 8A and 8B is substantially the same as the optical sensor package 100 of FIGS. 1A to 1C, except that the optical sensor package 100 of FIGS. 8A and 8B includes a second partition wall portion extending in a direction of the first surface (e.g., surface in the +Z direction) along an edge of the package substrate whereas the optical sensor package 100 of FIGS. 1A to 1C includes the partition wall PTW only between the light-emitting unit 110 and the light-receiving unit 130 (or the semiconductor chip 120). Hereinafter, a difference will be mainly described, and the same description as that made above will be omitted.

Referring to FIGS. 8A and 8B, the molding member ENC may include the partition wall PTW including a first partition wall portion PTW1 disposed between the light-emitting unit 110 and the light-receiving unit 130 (or the semiconductor chip 120) and a second partition wall portion PTW2 extending in a direction of the first surface S1 (e.g., surface in the +Z direction) along an edge of the package substrate SUB.

According to a method of manufacturing the optical sensor package 100 of the disclosure described below, the partition wall PTW may be formed through a dispensing molding technique.

In detail, the molding member ENC formed through a transfer molding technique may include the groove HM formed in a thickness direction between the light-emitting unit 110 and the light-receiving unit 130 (or the semiconductor chip 120) and along the edge of the package substrate SUB. For example, the groove HM may have a number ‘8’ shape in a plan sectional view.

The groove HM of the molding member ENC may be filled with an opaque material. The opaque material may be preferably formed of a material having a low light transmittance to light emitted from the light-emitting unit 110 in order to reduce the incidence of light emitted from the light-emitting unit 110 on the light-receiving unit 130. For example, the opaque material may be a black epoxy molding compound (EMC).

In an embodiment, a bottom surface of the partition wall PTW (or the opaque material) may contact the package substrate SUB, and a top surface of the partition wall PTW (or the opaque material) may be exposed to the outside.

In an embodiment, the top surface of the partition wall PTW (or the opaque material) may be coplanar with a top surface of the molding member ENC, and side surfaces connecting the top surface and the bottom surface of the partition wall PTW (or the opaque material) may contact the molding member ENC. In other words, the groove HM may have a trench structure with boundary surfaces where the partition wall PTW (or the opaque material) and the molding member ENC contact each other as side surfaces and the package substrate SUB as a bottom surface.

As such, because the optical sensor package 100 includes the partition wall PTW for isolating the light-emitting unit 110 from the light-receiving unit 130, crosstalk in which light emitted from the light-emitting unit 110 is directly incident on the light-receiving unit 130 may be further prevented, thereby improving the sensing sensitivity of the optical sensor package 100.

The optical sensor package 100 may include the molding member ENC including a first molding member ENC1 disposed on a top surface of an exposed portion of the package substrate SUB and the light-emitting unit 110, a second molding member ENC2 disposed on a top surface of another exposed portion of the package substrate SUB and the semiconductor chip 120, and a third molding member ENC3 surrounding an outer circumferential surface of the partition wall PTW.

In an embodiment, the molding member ENC may be formed of a light-transmitting material. For example, the molding member ENC may include a clear molding compound (CMC). The molding member ENC may guide light emitted from the light-emitting unit 110 to be transmitted to the detection target of the optical sensor package 100.

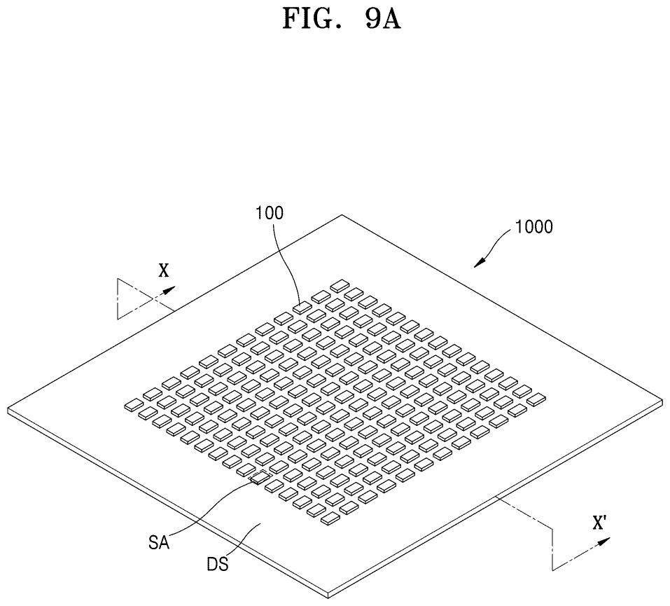

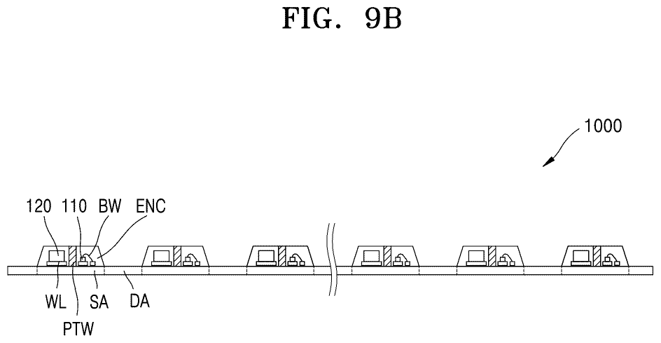

FIG. 9A is an external perspective view illustrating a substrate strip for an optical sensor package, according to an embodiment. FIG. 9B is a cross-sectional view illustrating the substrate strip taken along line X-X′ of FIG. 9A.

First, as shown in FIGS. 9A and 9B, a substrate strip 1000 for an optical sensor package according to an embodiment may include substrate units SA that become substrates of individual optical sensor packages after singulation (or a cutting process) and a dummy area DA excluding the substrate units.

For example, the substrate strip 1000 may be a printed circuit board (PCB) array or a thin panel structure formed long in a longitudinal direction so that a wiring layer WL corresponding to the first element PE1, the second element PE2, the third element PE3, and the fourth element PE4 described with reference to FIGS. 1A to 8B is formed and a plurality of optical sensor elements (e.g., the light-emitting unit 110 and the semiconductor chip 120) are integrally mounted.

The substrate strip 1000 may be a support having sufficient strength and durability to support the plurality of optical sensor elements (e.g., the light-emitting unit 110 and the semiconductor chip 120), a bonding wire BW corresponding to the first conductive member W1, the second conductive member W2, and the third conductive member W3 described with reference to FIGS. 8A and 8B, the partition wall PTW for an individual element, and the molding member ENC for an individual element.

A plurality of optical sensor packages 100 may be arranged in an n×m matrix in the longitudinal direction and a width direction at regular intervals on the substrate strip 1000.

The bonding wire BW that electrically connects the optical sensor element (e.g., the light-emitting unit 110) to the wiring layer WL may be a signal transmission medium capable of transmitting an electrical signal between the optical sensor element (e.g., the light-emitting unit 110) and the wiring layer WL to the outside.

The partition wall PTW is a structure for preventing light emitted from the light-emitting unit 110 from being directly incident on the light-receiving unit 130 (see FIG. 1A) disposed on the semiconductor chip 120 and may be formed through dispensing molding on the substrate strip 1000. The partition wall PTW may be disposed between the light-emitting unit 110 and the light-receiving unit (or the semiconductor chip 120).

The partition wall PTW is preferably formed of a material having a low transmittance to light emitted from the light-emitting unit 110. For example, the partition wall PTW may be formed by using a black epoxy molding compound (EMC).

Also, the molding member ENC for an individual element may be formed through transfer molding on the substrate strip 1000 in a shape individually surrounding the optical sensor elements (e.g., the light-emitting unit 110 and the semiconductor chip 120) and the bonding wires BW.

The molding member ENC may include a light-transmitting encapsulant such as a CMC capable of transmitting external light to the optical sensor package 100 or transmitting light of the optical sensor package 100 to the outside at all times. However, the disclosure is not limited thereto, and a reflective encapsulant such as a white epoxy molding compound (WEMC) may be used.

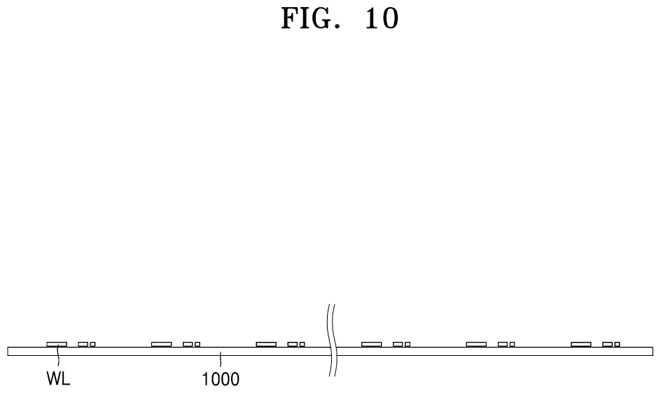

FIGS. 10 to 15 are cross-sectional views sequentially illustrating a process of manufacturing the substrate strop for an optical sensor package of FIGS. 9A and 9B.

Referring to FIGS. 10 to 15, a process of manufacturing the optical sensor package 100 according to an embodiment will be sequentially described.

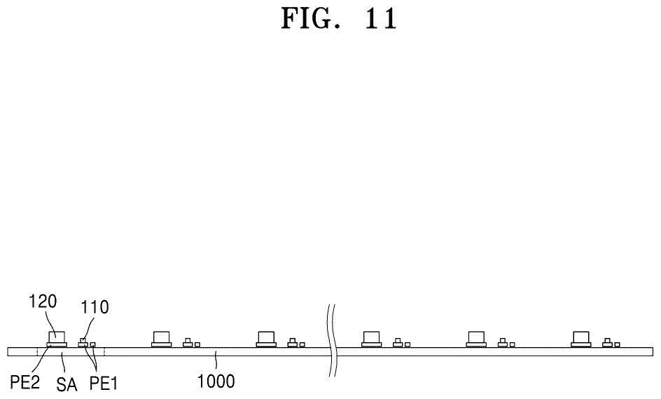

First, as shown in FIG. 10, the substrate strip 1000 may be prepared, and the wiring layer WL may be formed on the substrate 1000. In this case, the wiring layer WL may correspond to the first element PE1, the second element PE2, the third element PE3, and the fourth element PE4. Next, shown in FIG. 11, optical sensor elements may be mounted on each substrate unit SA of the substrate strip 1000. For example, the light-emitting unit 110 may be connected to the first element PE1, and the semiconductor chip 120 may be connected to the second element PE2.

In this case, although some of sensor elements disposed on the substrate unit SA are schematically illustrated in an enlarged or greatly simplified manner to aid description of a manufacturing process in FIG. 11, a shape and a type are not limited to those in FIG. 11 and various modifications and alterations may be made.

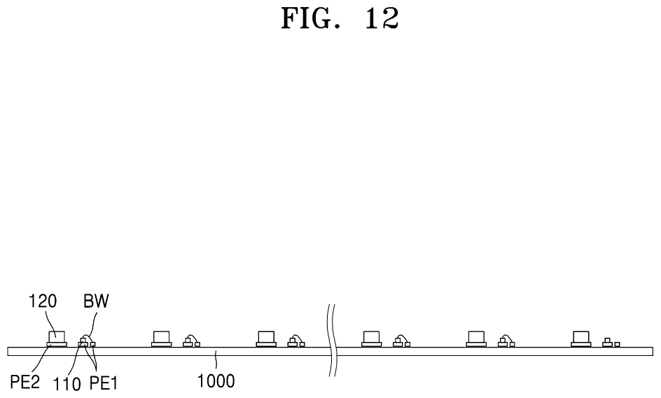

Next, as shown in FIG. 12, the optical sensor elements (e.g., the light-emitting unit 110) and the wiring layer (e.g., the first element PE1) may be electrically connected through the bonding wire BW.

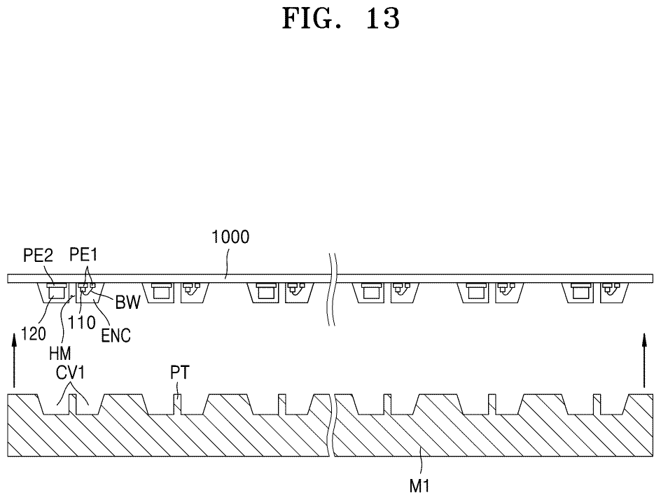

Next, as shown in FIG. 13, the molding member ENC for an individual element may be formed through transfer molding on the substrate strip 1000 in a shape individually surrounding the optical sensor elements (e.g., the light-emitting unit 110 and the semiconductor chip 120) and the bonding wire BW.

As shown in FIG. 13, the transfer molding may be performed by turning over the substrate strip 1000 so that first cavities CV1 provided in a first mold M1 and the substrate units SA are mounted and fixed to face each other and then providing a CMC to the first cavities CV1 to form the molding member ENC for an individual element through reverse molding.

In this case, the first mold M1 may include a protrusion PT at a position corresponding to the groove HM. A shape of the protrusion PT may correspond to a shape of the groove HM. For example, when the protrusion PT has a rectangular parallelepiped shape, the groove HM formed when the substrate strip 1000 and the first mold M1 are separated may have a well structure having a rectangular parallelepiped shape. That is, the groove HM may be a cavity having the package substrate SUB exposed in a rectangular shape as a bottom surface and an area of the molding member EMC exposed in a thickness direction along the bottom surface as a side surface.

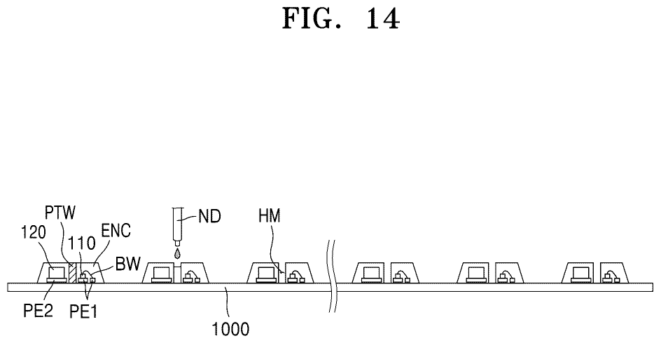

Next, as shown in FIG. 14, the partition wall PTW for an individual element may be formed through dispensing molding. The dispensing molding may use a method of applying a liquid black epoxy molding compound (EMC) to an inner side of the groove HM by using a discharge needle ND.

Next, a polishing process of smoothing a top surface of the partition wall PTW and a top surface of the molding member ENC may be performed so that the top surface of the partition wall PTW is coplanar with the top surface of the molding member ENC.

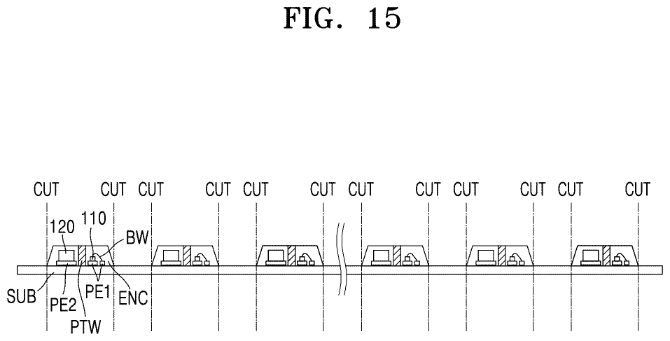

Next, as shown in FIG. 15, singulation may be performed by cutting into individual optical sensor packages along a cutting line CUT for each array.

As such, according to a method of manufacturing an optical sensor according to an embodiment, a manufacturing process in an optical sensor package manufacturing stage may be minimized, thereby reducing process time and manufacturing cost.

FIG. 16 is a flowchart for describing a method of manufacturing an optical sensor package, according to an embodiment.

Referring to FIGS. 9A to 15, a method of manufacturing an optical sensor package according to an embodiment may include operation S100 of mounting sensor elements such as the light-emitting unit 110 and the light-receiving unit 130 on each of the substrate units SA, operation S200 of forming the molding member ENC on each of the substrate units SA by using an encapsulant, operation of S300 of forming the partition wall PTW through dispensing molding, and singulation operation S400 of cutting the substrate strip 1000 into the substrate units SA.

Operation S100 of mounting the sensor elements may further include mounting the semiconductor chip 120 on the substrate units SA. In this case, the light-receiving unit 130 may be disposed on at least one of the semiconductor chip 120 and the substrate unit SA opposite to the light-emitting unit 110 with respect to the semiconductor chip 120.

A height from a top surface of the substrate strip 1000 to a top surface of the semiconductor chip 120 may be greater than a height from the top surface of the substrate strip 1000 to a top surface of the light-emitting unit 110.

Operation S200 of forming the molding member may include performing transfer molding by using a CMC as an encapsulant. In this case, the transfer molding may be performed by turning over the substrate strip so that the first cavities CV1 provided in the first mold M1 and the substrate units SA are mounted and fixed to face each other and then providing a CMC to the first cavities CV1 through reverse molding.

In this case, the first mold M1 may include the protrusion PT at a position corresponding to the groove HM. A shape of the protrusion PT may correspond to a shape of the groove HM. For example, when the protrusion PT has a rectangular parallelepiped shape, the groove HM formed when the substrate strip 1000 and the first mold M1 are separated may have a well structure having a rectangular parallelepiped shape. That is, the groove HM may be a cavity having the package substrate SUB exposed in a rectangular shape as a bottom surface and an area of the molding member ENC exposed in a thickness direction along the bottom surface as a side surface.

Operation S300 of forming the partition wall PTW may include performing dispensing molding by using a black epoxy molding compound (EMC) as an encapsulant. The dispensing molding may use a method of applying a liquid black epoxy molding compound (EMC) to an inner side of the groove HM by using the discharge needle ND.

Next, polishing operation of smoothing a top surface of the partition wall PTW and a top surface of the molding member ENC may be further included.

Singulation operation S400 may include cutting the substrate strip 1000 into the substrate units SA.

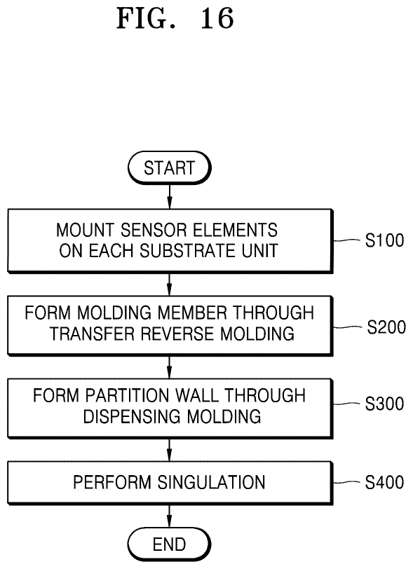

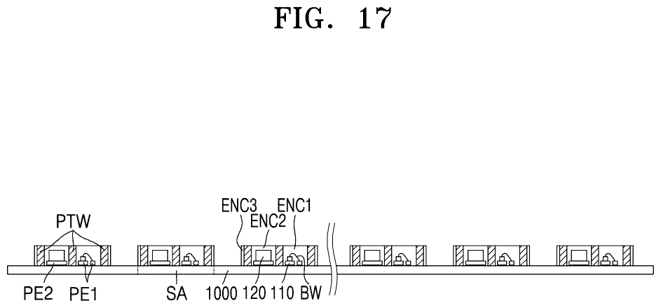

FIG. 17 is a cross-sectional view illustrating a substrate strip for an optical sensor package, according to an embodiment.

The embodiment of FIG. 17 is substantially the same as the embodiment of FIG. 9B, except that a shape of the partition wall PTW and shapes of the first, second, and third molding members ENC1, ENC2, and ENC3 are different. Hereinafter, a difference will be mainly described, and the same description as that made above will be omitted.

The molding member ENC may include the groove HM formed in a thickness direction between the light-emitting unit 110 and the light-receiving unit 130 (or the semiconductor chip 120) and along an edge of the package substrate SUB. For example, the groove HM may have a number ‘8’ shape in a plan sectional view. Accordingly, the molding member ENC may include the first molding member ENC1 that is an area including the light-emitting unit 110 surrounded by the partition wall PTW, the second molding member ENC2 that is an area including the light-receiving unit (or the semiconductor chip 210) surrounded by the partition wall PTW, and the third molding member ENC3 that is an edge area formed along an outer circumferential surface of the partition wall PTW.

The groove HM of the molding member ENC may be filled with an opaque material. The opaque material may be preferably formed of a material having a low light transmittance to light emitted from the light-emitting unit 110 in order to reduce the incidence of light emitted from the light-emitting unit 110 on the light-receiving unit 130. For example, the opaque material may be a black epoxy molding compound (EMC).

In an embodiment, a bottom surface of the partition wall PTW (or the opaque material) may contact the package substrate SUB, and a top surface of the partition wall PTW (or the opaque material) may be exposed to the outside.

In an embodiment, the top surface of the partition wall PTW (or the opaque material) may be coplanar with a top surface of the molding member ENC, and side surfaces connecting the top surface and the bottom surface of the partition wall PTW (or the opaque material) may contact the molding member ENC. In other words, the groove HM may have a trench structure with boundary surfaces where the partition wall PTW (or the opaque material) and the molding member ENC contact each other as side surfaces and the package substrate SUB as a bottom surface.

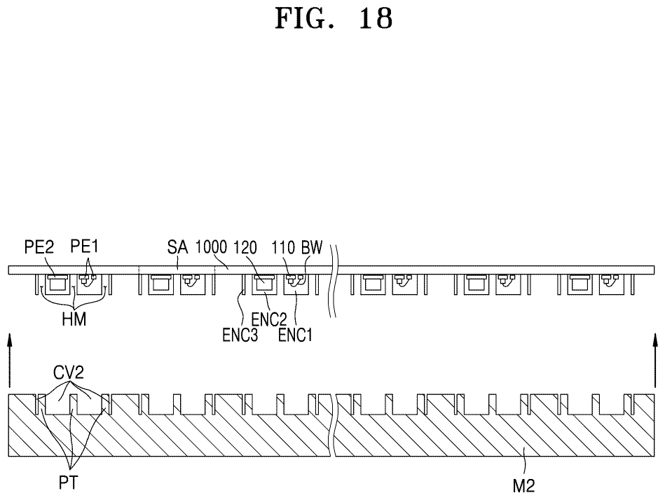

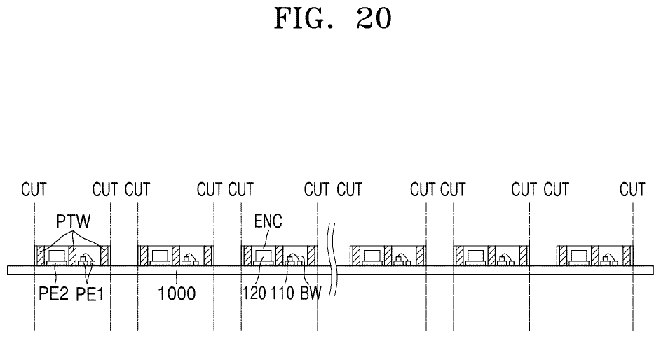

FIGS. 18 to 20 are cross-sectional views for describing a process of manufacturing the substrate strip for an optical sensor package of FIG. 17. The embodiment of FIG. 17 is substantially the same as the embodiment of FIG. 9B, except that a shape of the partition wall PTW and shapes of the first, second, and third molding members ENC1, ENC2, and ENC3 are different, and thus, the description of FIGS. 10 to 12, which describe substantially the same process, will be omitted.

As shown in FIG. 18, the molding member ENC for an individual element may be formed through transfer molding on the substrate strip 1000 in a shape that individually surrounds the optical sensor elements (e.g., the light-emitting unit 110 and the semiconductor chip 120) and the bonding wire BW.

As shown in FIG. 18, the transfer molding may be performed by turning over the substrate strip 1000 so that second cavities CV2 provided in a second mold M2 and the substrate units SA are mounted and fixed to face each other and then providing a CMC to the second cavities CV2 to form the first, second, and third molding members ENC1, ENC2, and ENC3 for an individual element through reverse molding.

In this case, the second mold M2 may include the protrusion PT at a position corresponding to the groove HM. A shape of the protrusion PT may correspond to a shape of the groove HM. For example, when a plan sectional shape of the protrusion PT is a number ‘8’ shape, the groove HM formed when the substrate strip 1000 and the second mold M2 are separated may have a trench structure having a number ‘8’ shape in a plan sectional view. That is, the groove HM may be a cavity having the package substrate SUB exposed in a number ‘8’ plan sectional shape as a bottom surface and an area of the molding member ENC exposed in a thickness direction along the bottom surface as a side surface.

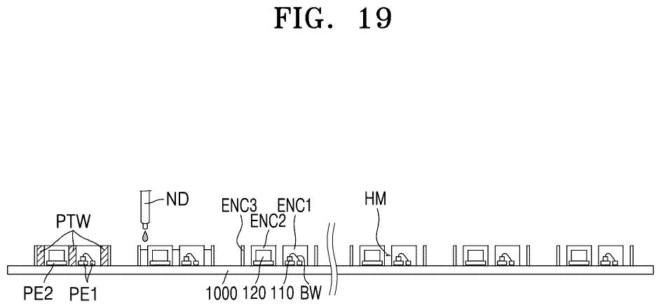

Next, as shown in FIG. 19, the partition wall PTW for an individual element may be formed through dispensing molding. The dispensing molding may use a method of applying a liquid black epoxy molding compound (EMC) to an inner side of the groove HM by using the discharge needle ND.

Next, a polishing process of smoothing a top surface of the partition wall PTW and a top surface of the molding member ENC may be performed so that the top surfaces of the partition wall PTW and the molding member ENC are coplanar with each other.

Next, as shown in FIG. 19, singulation may be performed by cutting into individual optical sensor packages along the cutting line CUT for each array.

As such, according to a method of manufacturing an optical sensor according to an embodiment, a manufacturing process in an optical sensor package manufacturing stage may be minimized, thereby reducing process time and manufacturing cost.

Those of ordinary skill in the art related to the present embodiments may understand that various changes in form and details can be made therein without departing from the scope of the characteristics described above. Therefore, the disclosed methods should be considered in a descriptive point of view, not a restrictive point of view. The scope of the present disclosure is defined by the appended claims rather than by the foregoing description, and all differences within the scope of equivalents thereof should be construed as being included in the present disclosure.

Because an optical sensor package according to embodiments prevents crosstalk in which light emitted from a light-emitting unit is directly incident on a light-receiving unit, the sensing sensitivity of the optical sensor package may be improved.

Because a method of manufacturing an optical sensor package according to an embodiment minimizes a manufacturing process in a package manufacturing stage, process time and manufacturing cost may be reduced.

Effects of the embodiments are not limited thereto, and other unmentioned effects will be apparent to one of ordinary skill in the art to which the embodiments pertain from the present specification and the attached drawings.

What is claimed is:

1. An optical sensor package comprising:
a light-emitting unit disposed on a package substrate and configured to emit first light toward a target;
a light-receiving unit disposed on the package substrate and configured to receive second light obtained when the first light is reflected from the target; and
a molding member formed on the package substrate to surround a top surface of an exposed portion of the package substrate, the light-emitting unit, and the light-receiving unit, the molding member comprising a groove formed in a thickness direction between the light-emitting unit and the light-receiving unit,
wherein the groove is filled with an opaque material.

2. The optical sensor package of claim 1, wherein a bottom surface of the opaque material contacts the package substrate, and a top surface of the opaque material is exposed to outside.

3. The optical sensor package of claim 2, wherein the top surface of the opaque material is coplanar with a top surface of the molding member.

4. The optical sensor package of claim 2, wherein side surfaces connecting the top surface to the bottom surface of the opaque material contact the molding member.

5. The optical sensor package of claim 1, wherein the molding member is formed of a clear molding compound, and the opaque material is a black epoxy molding compound.

6. The optical sensor package of claim 1, wherein the groove has a rectangular parallelepiped shape.

7. The optical sensor package of claim 1, wherein the target comprises an identification material configured to excite light of a first wavelength into light of a second wavelength different from the first wavelength, and the first light is light of the first wavelength and the second light is light of the second wavelength.

8. The optical sensor package of claim 7, wherein the identification material comprises a lanthanide material.

9. The optical sensor package of claim 1, further comprising a semiconductor chip disposed on the package substrate,
wherein the light-receiving unit is disposed on at least one of the semiconductor chip and the package substrate opposite to the light-emitting unit with respect to the semiconductor chip.

10. The optical sensor package of claim 9, wherein a height from a top surface of the package substrate to a top surface of the semiconductor chip is greater than a height from the top surface of the package substrate to a top surface of the light-emitting unit.

11. A method of manufacturing an optical sensor package, the method comprising:
mounting sensor elements including a light-emitting unit and a light-receiving unit, on each of substrate units;
forming, on each of the substrate units, a molding member comprising a groove formed in a thickness direction between the light-emitting unit and the light-receiving unit; and
filling the groove with an opaque material.

12. The method of claim 11, wherein the forming of the molding member comprises performing transfer molding by using a clear molding compound.

13. The method of claim 12, wherein the performing of the transfer molding comprises:
arranging a mold on a substrate strip so that cavities provided in the mold and the substrate units are mounted and fixed to face each other; and
providing the clear molding compound to the cavities.

14. The method of claim 11, wherein the filling of the groove comprises performing dispensing molding by injecting an encapsulant into the groove by using a black epoxy molding compound as the encapsulant.

15. The method of claim 11, further comprising cutting a substrate strip into the substrate units.
